(19) United States
(12) Patent Application Publication
(10) Pub. No.: US 2008/0298012 A1
(43) Pub. Date: Dec. 4, 2008

(54) HOLDING BASE FOR A RADIATOR ASSEMBLY

(76) Inventor: WEN-JI LAN, Kaohsiung (TW)

Correspondence Address: G. LINK CO., LTD., 3550 BELL ROAD, MINOOKA, IL, 60447, US

(21) Appl. No.: 11/757,396

(22) Filed: Jun. 4, 2007

(51) Int. Cl. H05K 7/20

(52) U.S. Cl. 361/688

(57) ABSTRACT

A holding base for a radiator assembly includes a frame, at least a secure part and at least a threaded part. The frame is attached to a circuit board and provides a space for receiving a heat generating component on the circuit board. The secure part provides an elongated projection rib at two lateral sides of said frame and provides an engaging block at the middle of the projection rib for engaging with the first type radiator assembly. The threaded part is disposed at the frame for being joined to the second type radiator assembly with a threaded fastener.

### BACKGROUND OF THE INVENTION

1. Field of the Invention

The present invention is related to a holding base and particularly to a holding base capable of being attached to different type radiator assemblies.

2. Brief Description of the Related Art

The conventional radiator assembly as shown in FIGS. 1 and 2 is mounted to a holding device 6 attached to a circuit board 7. The holding device 6 has a hollow space to receive a heat generating component 8 such as a central processing unit (CPU)on the circuit board 7. Then, a radiator assembly 9 is mounted to a corresponding position of the holding device 6. Two lateral sides of the radiator assembly 9 have an engaging device 91 with an engaging opening 911 to engaging with an engaging block 62 provided on the holding device 6. Thus, the heat from the heat generating component 8 can be dissipated with the radiator assembly 9 via the heat sink 92, guide heat pipes 93 and cooling fan 94 provided in the radiator assembly 9.

Besides, Taiwan Utility Model No, M302241 discloses a holding device engaging with the radiator assembly with bolts being fastened to threaded holes provided at holding device.

However, it can be seen from the preceding prior art the conventional holding device shown in FIGS. 1 and 2 is not suitable for the prior disclosed in Taiwan Utility Model No. M302241. By the same token, the holding device for the radiator assembly disclosed in Taiwan Utility No. M302241 is incapable of fitting with the radiator assembly shown in FIGS. 1 and 2.

### SUMMARY OF THE INVENTION

In order to overcome the preceding problems, an object of the present invention is to provide a holding base for a radiator assembly suitable of either threading fastening or block engaging.

Another object of the present invention is to provide a holding base for a radiator assembly with good compatibility.

According, a holding base for a radiator assembly according to the present invention includes a frame, at least a secure part and at least a threaded part. The frame is attached to a circuit board and provide a space for receiving a heat generating component on the circuit board. The secure part provides an elongated projection rib at two lateral sides of said frame and provides an engaging block at the middle of the projection rib for engaging with the first type radiator assembly. The threaded part is disposed at the frame for being joined to the second type radiator assembly with a threaded fastener.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view illustrating the detached conventional radiator assembly;

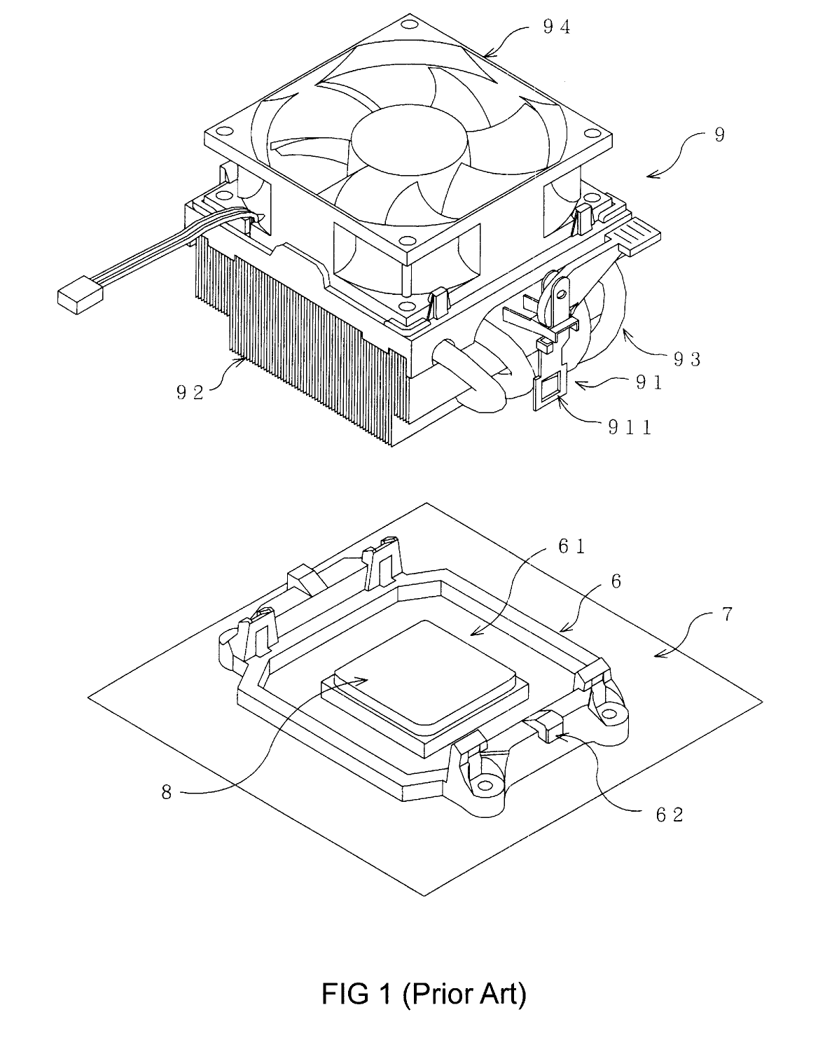

FIG. 2 is a perspective view illustrating the conventional radiator assembly shown in FIG. 1 being assembled as a unit;

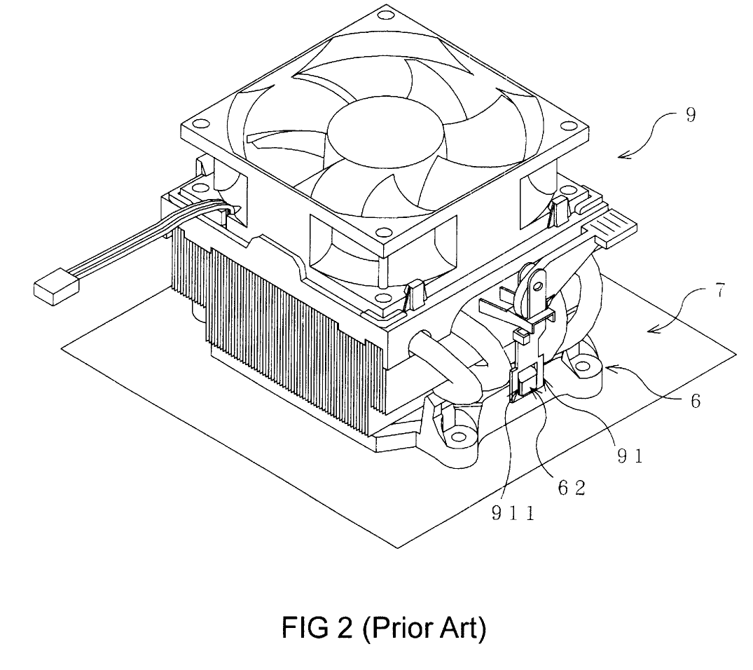

FIG. 3 is a perspective view of a holding base for a radiator assembly according to the present invention illustrating the holding base in a state of being detached from the first type radiator assembly:

FIG. 4 is a perspective view of a holding base for a radiator assembly according to the present invention illustrating the holding base in a state of holding the first type radiator assembly;

FIG. 5 is a perspective view of a holding base for a radiator assembly according to the present invention illustrating the holding base in a state of being detached from the second type radiator assembly; and

FIG. 6 is a perspective view of a holding base for a radiator assembly according to the present invention illustrating the holding base in a state of holding the second type radiator assembly;

### DETAILED DESCRIPTION OF THE INVENTION

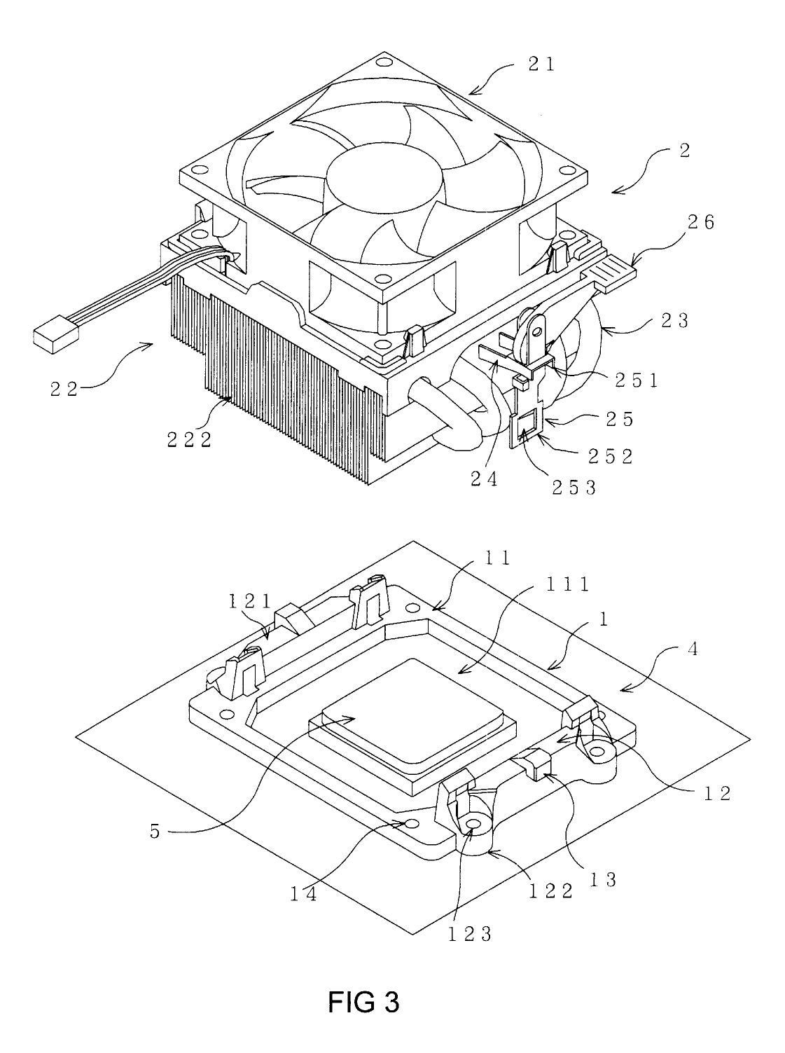

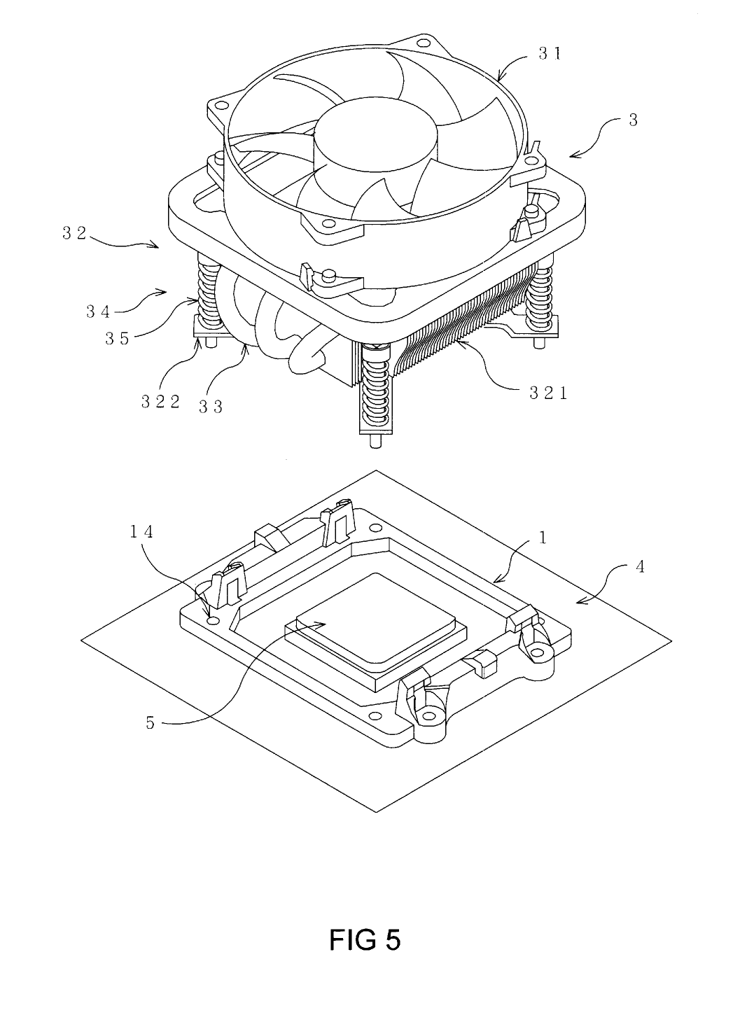

Referring to FIGS. 3 and 5, a holding base 1 according to the present invention is employed to allow the first type radiator assembly 2 or the second type radiator assembly 3 being tightly attached to a circuit board 4 for heat from a heat generating component 5 on the circuit board 4 being dissipated effectively.

The circuit board 4 shown in FIGS. 3 and 5 is a mother board of a desktop computer. The heat generating component 5 is a central processing unit (CPU) chip. Of course, the circuit board 4 can be an electronic component other than CPU such as the north/south bridge chips.

The holding base 1 shown in FIG. 3 includes a frame 11, a plurality of engaging parts 13 and a plurality of threaded fastening parts 14. The frame 11 provides a rectangular shape with a rectangular space 111. When the holding base 1 is attached to the circuit board 4, the heat generating component 5 is located in the center of the space 111 for the bottom of the first radiator assembly 2 contacting with the heat generating component 5 sa as to conducting heat from heat generating component 5.

The holding base 1 shown in FIG. 3 has two opposite secure parts 12 and each secure part 12 has an elongated projection rib 121 with two ends of the projection rib 121 having a screw seat 122 respectively. The screw seat 122 has an internal threaded hole 123 for engaging with the circuit board 4 with a bolt (not shown).

Further, each of the secure parts 12 further provides an engaging block 13 at middle of the projection rib 121 for engaging the radiator assembly 2 so that the radiator assembly 2 is capable of being attached to the frame 11.

The threaded fastening parts 14 are disposed at four corners of the frame 11 and each of the threaded fastening parts 14 has a threaded hole piercing the frame 11 for the corresponding parts of the radiator assembly 2 being engaged to the frame 11.

The first type radiator assembly 2 included a cooling fan 21, a heat sink 22, a plurality of guide heat pipes 23, a press member 24, a pair of engaging members 25 and a handle members 26. The cooling fan 21 is disposed on top of the heat sink 32 to induce fluid downward forcibly to dissipate heat from the heat generating component. The heat sink 22 includes a bottom seat (not shown)contacting the heavy generating component 5 and a plurality of cooling fins 222 made of material with good heat conductivity such as aluminum and copper. Each guide heat pipe passes through the cooling fins 222 horizontally to help dissipating heat evenly and rapidly. The press member 24 is am elongated lever across the radiator assembly 2 and disposed on top of the cooling 222 to intensify tightness between the bottom seat and the upper surface of the heat generating component 5.

The engaging members 25 are connected to two ends of the press member 24 respectively and each of the engaging members 25 has an upper pivot seat 251 for pivotally joining the respective handle member 26 and a lower engaging lug 252 with an engaging opening 253 for engaging the secure part 13. The respective handle member 25 is operated to rotate in a arrange of 180° and exert an upward pulling force to the lower engaging lug 252 against the secure part 13 such that the radiator assembly can be pressed against the circuit board 4 for the bottom seat of the heat sink 222 being capable of contacting the heat generating component 5 tightly. Because the press member 24, the engaging members 25 and the handle member 26 are prior art and no details will be describe further.

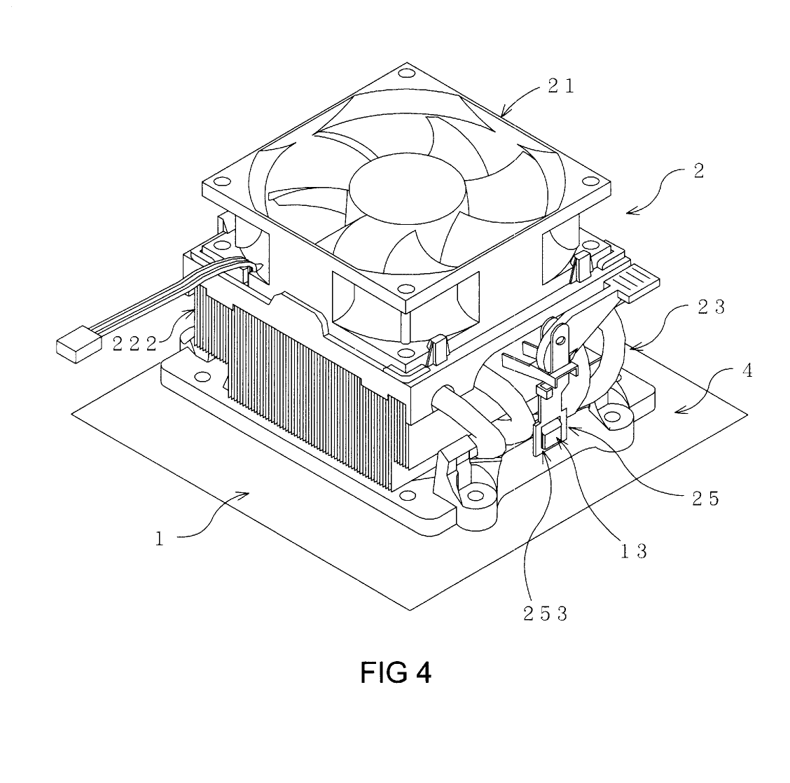

Referring FIGS. 3 and 4, the first type radiator assembly 2 is placed to the corresponding position at he holding base 1 and the engaging opening 25 of the respective engaging member 25 holds the bottom of the respective secure part 13 first. Then, the handle member 26 is stirred to a horizontal position to allow the respective engaging opening 253 tightening the secure part 13 effectively. In this way, the heat from the heat generating component 5 can be dissipated through the cooling fins 22, the guide heat pipe 23 and the cooling fan 21.

It is noted that the secure part 13 and the engaging member 25 shown in FIGS. 3 and 4 only examples and other engaging ways such as disclosure of Taiwan Utility Model No. 297009 providing an open groove type secure part can be used instead. The numbers of the secure part 13 and the engaging member 25 can be arranged based on the integral configuration of the radiator assembly instead of those in the preceding description.

Referring to FIG. 5, the second type radiator assembly 3 provides a circular upper frame 31 attached to a square lower frame and further includes, a cooling fan 3, a heat sink 32, a plurality of guide heat pipes 33, a plurality of threaded fasteners 34 and a plurality of elastic members 35. The cooling fan 31 is received in the circular upper frame 31. The cooling fan 3, the heat sink 32 and the guide heat pipes 33 provide the same functions as those arranged in the first type radiator assembly 2 and no detail will be describe further. The heat sink 32 has a square bottom seat (not shown) and a plurality of cooling fins 321. The bottom seat is attached to a locating member 322 with four corners of the locating member 322 extending a fixing end respectively. The fixing end has a through hole for a threaded fastener 34 being capable of engaging the radiator assembly 3 to holding seat 1 via the through hole. The threaded fastener 34 is a bolt with a lower threaded section and an upper non-thread section. The elastic members 35 are compression springs surrounding the respective threaded fastener 34 for the second type radiator assembly being able to contact the upper surface of the heat generating component 5 tightly.

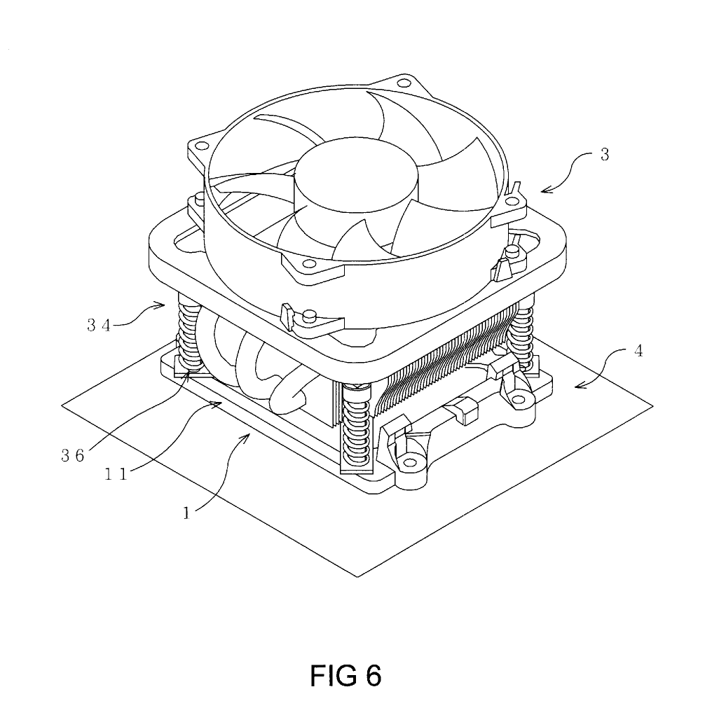

Referring FIG. 6 in company with FIG. 5, the second type radiator assembly 3 is located at a corresponding position at the holding base 1 and the threaded fasteners 34 engage with threaded holes of the fastening parts 14 of the holding base 1. In this way, the second type radiator assembly 3 can be mounted to the holding base 1 firmly.

It is noted that others fastening ways can be used instead of the fastening parts 14 and the threaded members 34 and the numbers of the fastening parts 14 and the threaded members 34 can be changed based on the integral configuration of the second type radiator assembly 3.

It is appreciated that the holding base 1 according to the present invention is capable of accommodating either the first type radiator assembly 2 or the second type radiator assembly 3. That is, the single holding base 1 is suitable for two different type radiator assemblies 2, 3 and provides excellent compatibility which is incapable of achieving with the prior art.

While the invention has been described with referencing to preferred embodiments thereof, it is to be understood that modifications or variations may be easily made without departing from the spirit of this invention, which is defined by the appended claims.

What is claimed is:

1. A holding base for a radiator assembly comprising:
a frame being attached to a circuit board and providing a space for receiving a heat generating component on the circuit board;
at least a secure part providing an elongated projection rib at two lateral sides of said frame and providing an engaging block at the middle of the projection rib for engaging with the radiator assembly; and
at least a threaded part being disposed at the frame for being joined to the radiator assembly with a threaded fastener.

2. The holding base for a radiator assembly as defined in claim 1, wherein the radiator assembly provides a square frame member and an engaging member at two opposite sides thereof with an engaging opening at the lower section of the respective engaging member to engage with the engaging block.

3. The holding base for a radiator assembly as defined in claim 1, wherein the radiator assembly provides a circular frame member for receiving a fan and the radiator assembly is attached to the frame with a bolt engaging with the threaded part respectively.
